(19) United States
(12) Patent Application Publication
(10) Pub. No.: US 2005/0199492 A1
(43) Pub. Date: Sep. 15, 2005

(54) Sputtering device

(76) Inventor: Nobuyuki Takahashi, Sagamihara (JP)

Correspondence Address: WENDEROTH, LIND & PONACK, L.L.P., 2033 K STREET N. W., SUITE 800, WASHINGTON, DC, 20006-1021, US

(21) Appl. No.: 11/074,678

(22) Filed: Mar. 9, 2005

(30) Foreign Application Priority Data
Mar. 10, 2004 (JP) 2004-66500

(51) Int. Cl. C23C 14/34

(52) U.S. Cl. 204/298.12

(57) ABSTRACT

The present invention is to provide a sputtering device in which a film can be formed to a large sized substrate efficiently and uniformity of forming film distribution is designed, which comprises a sputtering cathode group including a plurality of sputtering cathodes which are established at a specific arrangement in a direction perpendicular to a movable direction of a large sized substrate which moves in a specific direction. Note that it is preferred that the sputtering cathode is a round shape. It is preferred that the sputtering cathode group is a first sputtering cathode row comprising a plurality of sputtering cathodes which are arranged at specific intervals in the direction perpendicular to the movable direction of the large sized substrate. It is preferred that the sputtering cathode group has a second sputtering cathode row comprising a plurality of sputtering cathodes which are arranged at a specific distance to the first sputtering cathode row in the movable direction and which are arranged at positions where every sputtering cathodes in the first sputtering cathode row are not overlapped against the movable direction. It is preferred that centers of the sputtering cathodes constituting the first sputtering cathode row and centers of the sputtering cathodes constituting the second sputtering cathode row are positioned at regular intervals alternately when they are projected in the movable direction.

### BACKGROUND OF THE INVENTION

This invention relates to a sputtering device which is a film forming device for manufacturing a large size substrate such as a liquid-crystal display panel and a plasma display panel.

JP 2000-319779 A discloses a sputtering method and its device suitable for forming a film with small internal stress, especially for forming a film to a large sized substrate, the sputtering method being characterized in that a holder base on which a substrate is provided is moved along two straight lines located in a sputtering chamber so as to be able to move in counter directions in each line, the holder base is transferred onto the other line at each end of the lines, and both surfaces of the substrate are sputtered while the holder base is circulating, and the sputtering is carried out in a manner that an incident angle of sputtering particles is set at random.

An object of JP 11-189873 A is to increase the uniformity of the coating thickness and coating quality of a thin film formed on a large sized substrate in a compact magnetron sputtering electrode, and discloses a sputtering device in which sputtering is carried out by using a planar target to form a thin film on the substrate, wherein a sputtering electrode having a moving device for moving a magnetic circuit provided behind the target parallel to a surface of the substrate being at the opposite position, and a substrate holder holding the substrate at the position opposite to the sputtering electrode and having a rotation device for rotating the substrate with the center of the substrate as the axis.

In the sputtering device disclosed in JP 2000-319779, a thin film is formed on the substrate by moving the substrate against sputtering cathodes, the forming film distribution of the thin film depends on moving speed of the substrate in a moving direction of the substrate, and depends on the sputtering cathodes in a direction perpendicular to the moving direction. Moreover, in recent years, maximization of a substrate such that the size of the substrate is over 1 meter is advanced.

Accordingly, because it is necessary that a size of a sputtering cathode is made larger than a substrate, maximization of the sputtering cathode is advanced with maximization of the substrate, as a result, a target material must be maximized, so that it becomes difficult to obtain the target materials.

Because electric power supplied to the sputtering cathode has to be larger in order to get a specific forming film speed as the maximization of the sputtering cathode. it comes into problems in manufacture and safety. Furthermore, because the sputter target material consumes by continuation of sputtering, it has to be changed in a specific period, but the changing work becomes difficult due to the maximization of the sputter target material, and further problems in the safety are arisen.

Besides, as disclosed in JP 11-189873 A, the method for forming a thin film to the large sized substrate by moving the magnet circuit of the sputtering electrode to the substrate needs very accurate control in order to make the distribution of forming film even because the substrate has to be moved by inches.

### SUMMARY OF THE INVENTION

An object of the present invention is to provide a sputtering device in which a film can be formed to a large sized substrate efficiently and uniformity of forming film distribution is designed.

Accordingly, a sputtering device according to the present invention comprising a sputtering cathode group including a plurality of sputtering cathodes which are established at a specific arrangement in a direction perpendicular to a movable direction of a large sized substrate which moves in a specific direction. Note that it is preferred that the sputtering cathode is a round shape.

Besides, it is preferred that the sputtering cathode group is a first sputtering cathode row comprising a plurality of sputtering cathodes which are arranged at specific intervals in the direction perpendicular to the movable direction of the large sized substrate. Furthermore, it is preferred that the sputtering cathode group has a second sputtering cathode row comprising a plurality of sputtering cathodes which are arranged at a specific distance to the first sputtering cathode row in the movable direction and which are arranged at positions where every sputtering cathodes in the first sputtering cathode row are not overlapped against the movable direction.

Moreover, it is preferred that centers of the sputtering cathodes constituting the first sputtering cathode row and centers of the sputtering cathodes constituting the second sputtering cathode row are positioned at regular intervals alternately when they are projected in the movable direction.

According to the present invention, as round-shaped small sized sputtering cathodes are used because a plurality of the sputtering cathodes are arranged in the direction perpendicular to the movable direction, it becomes easy to get sputtering target materials and changing of the sputter target materials can be facilitated.

Moreover, in the case that film is formed at 1 μm by aluminum material, electric power supply has to be 50 KW when the film is formed by only one sputtering cathode, but when a plurality of small sized sputtering cathodes are used, for instance when five sputtering cathodes are used, electric power supply per one sputtering cathode is only 10 KW that is a fifth of the aforementioned electric power. As a result, there is an effect so that not only manufacturing of the sputtering cathode can be facilitated but also it is easy to maintain safety.

Besides, it is possible to design uniformity of forming film distribution by constituting a plurality of sputtering cathode rows positioning alternately.

### BRIEF DESCRIPTION OF DRAWINGS

The various features of novelty which characterize the invention are pointed out with particularity in the claims annexed to and forming a part of this specification. For a better understanding of the invention, its operating advantages, and specific objects attained by its use, reference should be had to the accompanying drawings and descriptive matters in which there are illustrated and described preferred working modes of the invention.

FIG. 1 is an explanation diagram showing arrangement of sputtering cathodes in a sputtering device according to embodiment of the present invention,

FIG. 2A is an explanation diagram showing a first sputtering cathode row and thickness distribution thereof, and

FIG. 2B is an explanation diagram showing a second sputtering cathode row and thickness distribution thereof, and further a total of the thickness distribution.

### DETAILED DESCRIPTION OF THE PREFERRED WORKING MODE

Hereinafter, an embodiment of the present invention is explained by the drawings.

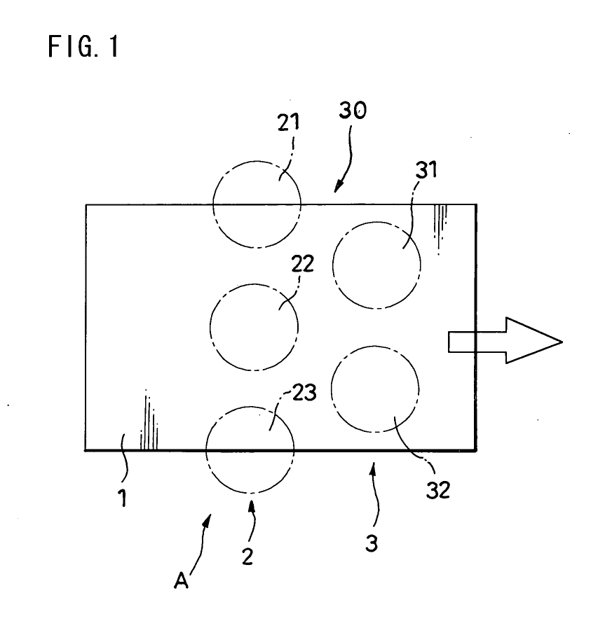

A sputtering device A according to an embodiment of the present invention is, as shown in FIG. 1, constituted of a large sized substrate 1 movable to one direction (forward) or two direction (forward and backward), a first sputtering cathode row 2 comprising a plurality of sputtering cathodes 21, 22, 23 arranged at regular intervals in a direction (hereinafter, saying a perpendicular direction) perpendicular to a movable direction of the large sized substrate 1, and a second sputtering cathode row 3 comprising a plurality of sputtering cathodes 31, 32 having their centers each of which is positioned each between the sputtering cathodes 21, 22, 23 constituting the first sputtering cathode row in the case of projecting in the movable direction and arranged at a specific distance in the movable direction from the first sputtering cathode row 2.

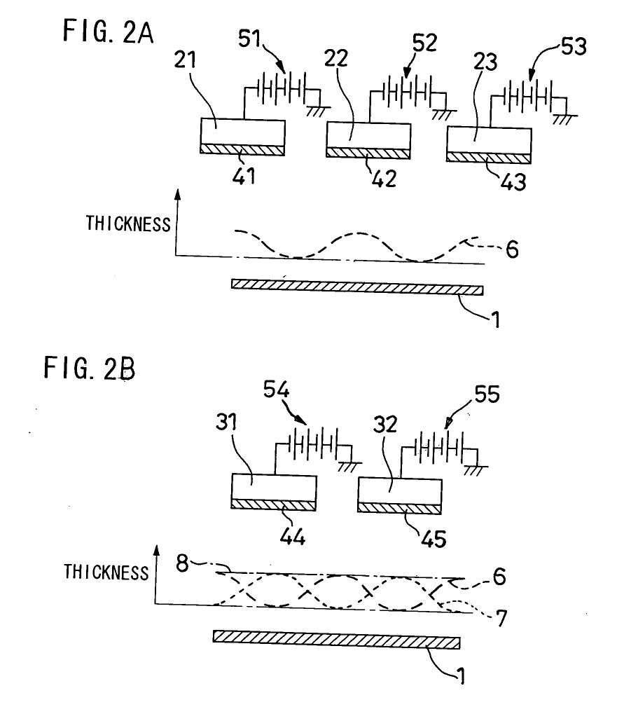

The first sputtering cathode row 2 comprises, as shown in FIG. 2A, electric power sources 51, 52, 53 in the sputtering cathodes 21, 22, 23 and ring-shaped sputter target materials 41, 42, 43 detachably installed on the sputtering cathodes 21, 22, 23, respectively. By the first sputtering cathode row 2, a thin film with film thickness as shown by a characteristic line 6 is formed on the large sized substrate 1.

The second sputtering cathode row 3 comprises, as shown in FIG. 2B, electric power sources 54, 55 in the sputtering cathodes 31, 32 and ring-shaped sputter target materials 44, 45 detachably installed on the sputtering cathodes 21, 32, respectively. By the second sputtering cathode row 3, a thin film with film thickness as shown by a characteristic line 7 is formed on the large sized substrate 1 and laminated to the film thickness as shown by the characteristic line 6, so that desired forming film distribution 8 can be gained.

Besides, the electric power sources 51, 52, 53, 54, 55 may be low power because the sputtering cathodes 21, 22, 23, 24, 25 can be miniaturized. Accordingly, an effect so that costs can be decreased can be achieved.

1. A sputtering device comprising a sputtering cathode group consisting of a plurality of sputtering cathodes arranged at specific intervals in a direction perpendicular to a movable direction of a large sized substrate moving in a specific direction.

2. A sputtering device according to claim 1, wherein said sputtering cathode is a round shape.

3. A sputtering device according to claim 1, wherein said sputtering cathode group comprises a first sputtering cathode row consisting of a plurality of said sputtering cathodes arranged at specific intervals in the direction perpendicular to the movable direction of the large sized substrate moving in the specific direction.

4. A sputtering device according to claim 3, wherein said sputtering cathode group further comprises a second sputtering cathode row arranged at a specific distance in the movable direction from said first sputtering cathode row and consisting of a plurality of said sputtering cathodes arranged at positions where said sputtering cathodes in said first sputtering cathode row are not overlapped in the movable direction respectively.

5. A sputtering device according to claim 4, wherein centers of said sputtering cathodes constituting said first sputtering cathode row and centers of said sputtering cathodes constituting said second sputtering cathode row are positioned alternately at regular intervals when they projected in the movable direction.

6. A sputtering device according to claim 2, wherein said sputtering cathode group comprises a first sputtering cathode row consisting of a plurality of said sputtering cathodes arranged at specific intervals in the direction perpendicular to the movable direction of the large sized substrate moving in the specific direction.

7. A sputtering device according to claim 6, wherein said sputtering cathode group further comprises a second sputtering cathode row arranged at a specific distance in the movable direction from said first sputtering cathode row and consisting of a plurality of said sputtering cathodes arranged at positions where said sputtering cathodes in said first sputtering cathode row are not overlapped in the movable direction respectively.

8. A sputtering device according to claim 7, wherein centers of said sputtering cathodes constituting said first sputtering cathode row and centers of said sputtering cathodes constituting said second sputtering cathode row are positioned alternately at regular intervals when they projected in the movable direction.
